(19) United States
(12) Patent Application Publication
(10) Pub. No.: US 2018/0342563 A1
(43) Pub. Date: Nov. 29, 2018

(54) OLED DISPLAY SUBSTRATE AND MANUFACTURING METHOD THEREOF, DISPLAY PANEL AND DISPLAY APPARATUS

(71) Applicant: BOE TECHNOLOGY GROUP CO., LTD., BEIJING (CN)

(72) Inventors: Juanjuan YOU, BEIJING (CN); Li SUN, BEIJING (CN)

(21) Appl. No.: 15/867,084

(22) Filed: Jan. 10, 2018

(30) Foreign Application Priority Data
May 26, 2017 (CN) 201710386907.X

(51) Int. Cl. H01L 27/32; H01L 51/56

(52) U.S. Cl. CPC H01L 27/3246; H01L 51/56; H01L 27/3248; H01L 27/323; H01L 27/322; H01L 2227/323

(57) ABSTRACT

The disclosure provides an OLED display substrate and a manufacturing method thereof, a display panel and a display apparatus. The OLED display substrate comprises a substrate which is partitioned into a plurality of light-emitting regions; and a pixel definition layer disposed on the substrate, on which each of opening holes corresponding to each of the light-emitting regions is provided; an uneven structure is also provided on a side of the pixel definition layer far away from the substrate.

### CROSS-REFERENCE TO RELATED APPLICATIONS

This application claims the priority right of Chinese Patent Application No. 201710386907.X as filed on May 26, 2017, the disclosure of which is incorporated herein in its entirety by reference.

### TECHNICAL FIELD

The present disclosure relates to an OLED display substrate and a manufacturing method thereof, a display panel and a display apparatus.

### BACKGROUND

AMOLEDs (Active Matrix Organic Light-Emitting Display) expand rapidly in the market of consumer electronic products in virtue of their good display picture quality.

As users' requirements on the display picture quality continue to increase, resolution of an OLED display substrate is higher and higher as well, and meanwhile, it also brings about new problems. For example, for such a light-emitting mode in which each of OLED devices in an OLED display substrate emits a white light, and then it is bonded with a color film substrate to carry out color display, since each of OLED devices is a white-light-emitting electroluminescent device, a light-emitting function layer in the white OLED devices corresponding to each of pixels is a whole-layer structure disposed on a pixel definition layer. While for a color-light-emitting mode in which each of OLED devices in an OLED display substrate emits a red/green/blue or other color light, for the sake of simplifying the fabrication process of OLED devices, a part of structural layers in a light-emitting function layer in the OLED devices corresponding to each of pixels are also connected together.

In this way, in the event that a certain pixel is involved in display for the OLED display substrate, owing to the fact that a structural layer in the light-emitting function layer of each of the OLED devices that is connected together suffers from a problem of a transverse electric conduction along the layer direction, when the pixel is in display, one or more pixels around it may also be lighted up at the same time. Thereby, a problem of cross-talk between pixels arises.

### SUMMARY

Embodiments of the disclosure adopt the following technical solutions.

In a first aspect, an embodiment of the disclosure provides an OLED display substrate, comprising: a substrate which is partitioned into a plurality of light-emitting regions; and a pixel definition layer disposed on the substrate, on which each of opening holes corresponding to each of the light-emitting regions is provided; wherein an uneven structure is also provided on a side of the pixel definition layer far away from the substrate.

Optionally, the uneven structure comprises a recessed structure.

Optionally, the uneven structure comprises a protruded structure.

Optionally, the OLED display substrate further comprises: a first electrode disposed on the substrate and corresponding to each of the light-emitting regions, the opening holes exposing at least a partial region of the first electrodes; a light-emitting function layer comprising a plurality of structural layers disposed in a laminated manner; wherein at least one of the plurality of structural layers is provided inside the opening holes, on the side of the pixel definition layer far away from the substrate and on the uneven structure.

Optionally, each of the plurality of structural layers in the light-emitting function layer is provided inside the opening holes, on the side of the pixel definition layer far away from the substrate and on the uneven structure.

Optionally, the light-emitting function layer is used to emit a white light.

Optionally, the opening holes are arranged in an array; in at least one row of the opening holes, the uneven structure is provided between every two adjacent opening holes.

Optionally, the opening holes are arranged in an array; in at least one column of the opening holes, the uneven structure is provided between every two adjacent opening holes.

Optionally, a cross-sectional shape of the uneven structure along a direction perpendicular to the OLED display substrate comprises at least one of a rectangle, a triangle, a regular trapezoid or an inverted trapezoid.

Optionally, the OLED display substrate further comprises a second electrode disposed on the light-emitting function layer.

Optionally, the substrate comprises a base substrate and a transistor array layer disposed on the base substrate.

In a second aspect, an embodiment of the disclosure provides a manufacturing method of an OLED display substrate. The manufacturing method comprises: providing a substrate which is partitioned into a plurality light-emitting regions; forming an thin film of insulating material on the substrate; and conducting a patterning process treatment on the thin film of insulating material to form a pixel definition layer; wherein each of opening holes corresponding to each of the light-emitting regions is formed on the pixel definition layer, and an uneven structure is also formed on a side of the pixel definition layer far away from the substrate.

Optionally, the uneven structure comprises a recessed structure.

Optionally, the uneven structure comprises a protruded structure.

Optionally, before the step of conducting the patterning process treatment on the thin film of insulating material to form the pixel definition layer, the manufacturing method further comprises: forming, on the substrate, a first electrode corresponding to each of the light-emitting regions; the opening holes to be formed exposing at least a partial region of the first electrode; after the step of conducting the patterning process treatment on the thin film of insulating material to form the pixel definition layer, the manufacturing method further comprises: forming a light-emitting function layer which comprises a plurality of structural layers disposed in a laminated manner; wherein at least one of the plurality of structural layers is provided inside the opening holes, on the side of the pixel definition layer far away from the substrate and on the uneven structure.

In a third aspect, an embodiment of the disclosure provides a display panel, comprising the above-mentioned OLED display substrate and a bonded substrate with respect to the OLED display substrate.

Optionally, the bonded substrate is a package cover plate, or a touch cover plate to which a touch electrode layer is attached, or a color film substrate.

In a fourth aspect, an embodiment of the disclosure provides a display apparatus, comprising the above-mentioned display panel.

### BRIEF DESCRIPTION OF THE DRAWINGS

In order to describe embodiments of the present disclosure or technical solutions in prior art more clearly, accompanying drawings which are necessary for description of the embodiments or the prior art will be introduced in brief in the following. Apparently, accompanying drawings as described below are merely some embodiments of the present disclosure, and for a person skilled in the art, other figures may also be obtained based on these accompanying drawings without inventive efforts.

FIG. 1 is a schematic section view illustrating a partial structure of an OLED display substrate provided by an embodiment of the disclosure;

FIG. 2 is a schematic section view illustrating a partial structure of an OLED display substrate provided by prior art;

FIG. 3 is a schematic section view illustrating a partial structure of an OLED display substrate provided by an embodiment of the disclosure;

FIG. 4 is a schematic section view illustrating a partial structure of an OLED display substrate provided by an embodiment of the disclosure;

FIG. 5 is a schematic section view illustrating a partial structure of an OLED display substrate provided by an embodiment of the disclosure;

FIG. 6 is a schematic section view illustrating a partial structure of an OLED display substrate provided by an embodiment of the disclosure;

FIG. 7 is a schematic section view illustrating a partial structure of an OLED display substrate provided by an embodiment of the disclosure;

FIG. 8 is a schematic section view illustrating a partial structure of an OLED display substrate provided by an embodiment of the disclosure;

FIG. 9 is a schematic section view illustrating a partial structure of an OLED display substrate provided by an embodiment of the disclosure;

FIG. 10 is a schematic section view illustrating a partial structure of an OLED display substrate provided by an embodiment of the disclosure; and

FIG. 11 is a schematic section view illustrating a partial structure of an OLED display substrate provided by an embodiment of the disclosure.

### DETAILED DESCRIPTION

Hereinafter, technical solutions in embodiments of the disclosure will be described clearly and completely in conjunction with accompanying drawings in the embodiments of the disclosure. Apparently, the embodiments to be described are merely a part of rather than all of embodiments of the disclosure. All of other embodiment, which can be obtained by those skilled in the art on the basis of the embodiments in the disclosure without inventive efforts, comes within the protection scope of the disclosure.

It is to be noted that, unless otherwise defined, all of terms (comprising technical and scientific terms) used in embodiments of the disclosure have the same meaning as commonly understood by those skilled in the art to which this disclosure belongs. It shall be further understood that terms, such as those defined in commonly used dictionaries, should be interpreted as having a meaning that is consistent with their meaning in the context of the related art, and shall not be interpreted in an idealized or overly formal sense unless explicitly defined herein.

For example, terms “first”, “second” and the like used in specification and claims of the patent application of the disclosure do not show any order, number or importance, but are only used to distinguish different constituent parts. A term “comprises”, “includes”, “contains” or the like means that an element or article ahead of this term encompasses element(s) or article(s) listed behind this term and equivalents thereof, but does not preclude the presence of other elements or articles. Terms “one side”, “the other side” and the like indicating azimuthal or positional relationship, which are azimuthal or positional relationships based on those shown in accompanying drawings, are merely simplified descriptions used to facilitate explanation of technical solutions of the disclosure, rather than indicate or suggest that the devices or elements referred to by them must have a specific azimuth, and must be constructed and operate in a specific azimuth, and thus cannot be understood as limitations on the disclosure.

When an organic Electro Luminescent (EL) layer in the light-emitting function layer of the OLED devices adopts some p-doped or n-doped materials, due to a relatively high transverse conductivity of the p-doped or the n-doped materials, it is easier to cause the problem of cross-talk between pixels. In order to solve the above problem of cross-talk, there is an attempt in the prior art to replace the p-doped or the n-doped materials with materials having a relatively low transverse conductivity, but this may cause a selection range of materials of the light-emitting function layer to be greatly decreased.

In view of this, in order to solve the problem in the prior art, embodiments of the disclosure provide an OLED display substrate and a manufacturing method thereof, a display panel and a display apparatus, which can raise an area of a light-emitting function layer laid on a pixel definition layer and increase its resistance, thereby raising a voltage drop (IR Drop) in the light-emitting function layer at which a cross-talk easily occurs, and effectively reducing the cross-talk between adjacent pixels. Moreover, a selection range of materials of the light-emitting function layer is increased.

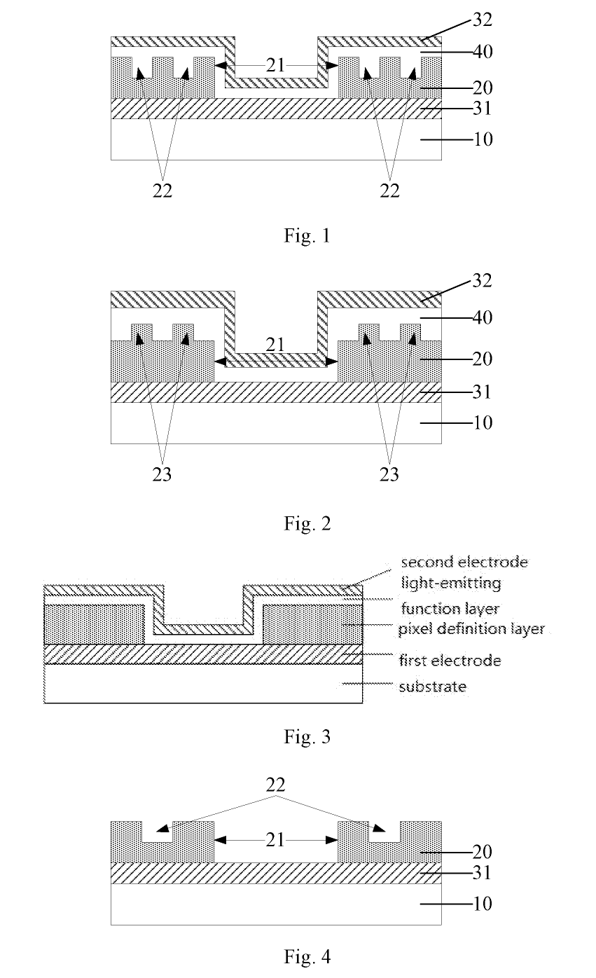

As shown in FIG. 1 or FIG. 2, an embodiment of the disclosure provides an OLED display substrate, including: a substrate 10 which is partitioned into a plurality of light-emitting regions; and a pixel definition layer 20 disposed on the substrate, on which each of opening holes 21 corresponding to each of the light-emitting regions is provided; wherein an uneven structure is also provided on a side of the pixel definition layer 20 far away from the substrate 10. For example, the uneven structure may comprise a recessed structure 22. As another example, the uneven structure may comprise a protruded structure 23.

Therefore, according to embodiments of the disclosure, the pixel definition layer 20 is made to have a detoured shape by means of providing a recessed structure and/or a protruded structure on it, as compared with a flat and straight pixel definition layer in the prior art as shown in FIG. 2, an area of the light-emitting function layer laid on the pixel definition layer 20 at which transverse cross-talk easily occurs can be caused to be larger. That is, a transverse length of a leakage layer laid on the pixel definition layer 20 is increased, and thus the IR Drop in a structural layer at which cross-talk easily occurs is increased. Consequently, the cross-talk between the pixels is reduced effectively. Moreover, the selection range of the materials of the light-emitting function layer may be increased.

For each of the above structures, it is to be noted that, those skilled in the art should understand that, the above-mentioned substrate 10 refers to a structure comprising a base substrate and a transistor array layer that is disposed on the base substrate, is used to control each of the OLED devices and is constituted by a plurality of transistors arranged in an array.

Referring to those as shown in FIG. 1 or FIG. 2, the aforesaid OLED display substrate further comprises a first electrode 31 disposed on the substrate 10 and corresponding to each of the light-emitting regions, and the aforesaid opening holes expose at least a partial region of the first substrate 31. For example, when the first electrode 31 is an anode in the OLED devices, an electrical connection between it and a drain electrode of a transistor is realized by a via hole on an insulating layer covering the transistor array layer. The specific structure may follow the prior art, and embodiments of the disclosure will not have limitation on this.

Furthermore, the aforesaid OLED display substrate further comprises a light-emitting function layer 40 disposed above the first electrode 31, the light-emitting function layer 40 may comprise, for example, a plurality of structural layers disposed in a laminated manner, such as a hole injection layer, a hole transportation layer, a light-emitting layer, an electron transportation layer, an electron injection layer and so on; wherein at least one of the plurality of structural layers in the above-mentioned light-emitting function layer 40 is provided inside the opening holes 21, on a side of the pixel definition layer 20 far away from the substrate and on the uneven structure (for example, inside the recessed structure 22 and/or on the protruded structure 23). That is, at least one of the plurality of structural layers is laid on the whole layer of the pixel definition layer 20.

The above-mentioned OLED display panel further comprises a second electrode 32 disposed on the light-emitting function layer 40. Herein, in case that the aforesaid first electrode 31 is an anode, the opposite second electrode 32 is a cathode. Because anodes of individual OLED devices are separate electrodes which are separated and do not contact with each other, for the sake of simplifying the process, referring to that as shown in FIG. 1, the second electrode 32 may be laid over the light-emitting function layer 40 by the whole layer. That is, cathodes of individual OLED devices are connected together to be an integral structure.

An uneven structure such as a recessed structure 22 and/or a protruded structure 23 is provided on a side of the pixel definition layer (PDL) 20 far away from the substrate 10. That is, an open direction of the recess of the recessed structure 22 faces the side away from the substrate 10, and a protrusive side of the protruded structure 23 faces the side away from the substrate 10. Embodiments of the disclosure will have no limitations on the specific shape, the number and the arrangement of the recessed structure 22 and/or protruded structure 23, as long as the recessed structure 22 and/or the protruded structure 23 is provided on the side of the pixel definition layer 20 far away from the substrate 10 to increase its effective area.

For example, the recessed structure 22 may be a groove, or a hole-like structure directly punching through the pixel definition layer 20.

In the aforesaid problem in the prior art as raised in the background, the problem of cross-talk between pixels is caused by a transverse leakage of electricity resulting from a relatively small transverse resistance of materials of a light-emitting function layer in the OLED devices. The “transverse” as mentioned here is relative to a light emitting direction of the OLED devices. Since the light emitting direction of the OLED devices is a direction perpendicular to the plane in which the light-emitting function layer lies, namely, a direction of directing from one electrode in one OLED device toward the other electrode opposed to it is a longitudinal direction, relatively, a direction in parallel to the plane in which the light-emitting function layer lies is a transverse direction. Because lights emitted from the OLED devices emit perpendicular to a direction of the plane in which the light-emitting function layer lies (i.e., along the longitudinal direction), the transverse leakage of electricity is invalid for promotion of light-emitting efficiency of the OLED devices.

Hereinafter, for the sake of conciseness, the light-emitting function layer (it may be one or more layers therein) laid on the pixel definition layer 20 at which cross-talk due to the transverse leakage of electricity easily occurs is called as a leakage layer. As can be obtained by the following formula of resistance, in terms of a given material of the luminescent functional layer, its resistivity p is constant, and the cross-sectional area is also constant (the cross-sectional area is determined by a thickness of the light-emitting function layer, and the too small thickness goes against fabrication of the OLED devices), so the resistance of the leakage layer can be increased by increasing its transverse length. Thus, the IR Drop (voltage drop, i.e., a potential difference across the resistance) of this layer is increased, and thereby, the effect of reducing cross-talk between adjacent pixels is achieved.

$$R = ρ \cdot \frac{L}{S} ;$$

wherein, R denotes a resistance, ρ denotes a resistivity, S denotes a cross-sectional area, and L denotes a length of a resistor.

Based on this, according to embodiments of the disclosure, the pixel definition layer 20 is made to have a detoured shape by means of providing an uneven structure such as a recessed structure and/or a protruded structure on it, as compared with a flat and straight pixel definition layer in the prior art as shown in FIG. 2, an area of the light-emitting function layer laid on the pixel definition layer 20 at which transverse cross-talk easily occurs can be caused to be larger. That is, a transverse length of a leakage layer laid on the pixel definition layer 20 is increased, and thus the IR Drop in a structural layer at which cross-talk easily occurs is increased. Consequently, the cross-talk between the pixels is reduced effectively. Moreover, the selection range of the materials of the light-emitting function layer may be increased.

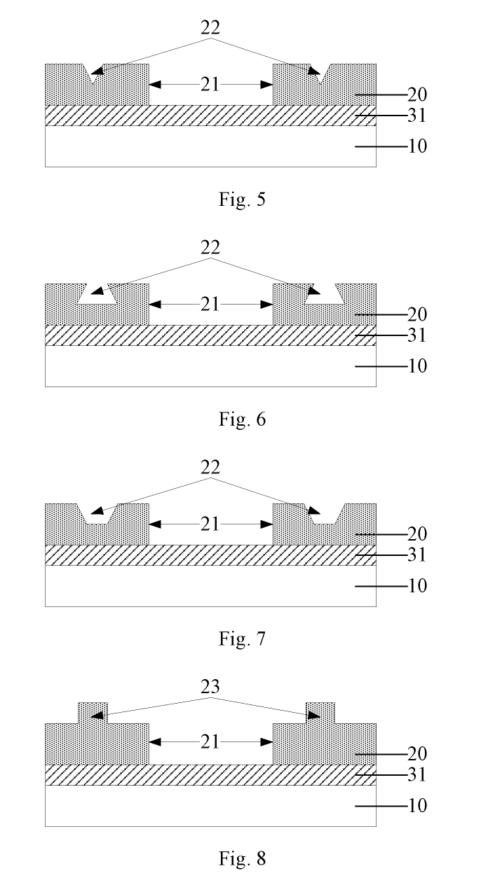

The above-mentioned detoured shape, i.e., a cross-sectional shape of the uneven structure such as the recessed structure 22 along a direction perpendicular to an OLED display panel may comprise, but is not limited to, at least one of a rectangle as shown in FIG. 4, a triangle as shown in FIG. 5, a regular trapezoid as shown in FIG. 6 and an inverted trapezoid as shown in FIG. 7. For example, as for a specific structure of the recessed structure 22, a pixel definition layer PDL of a specific shape may be realized by a photolithographic process, and the process is simple, and is easy to implement.

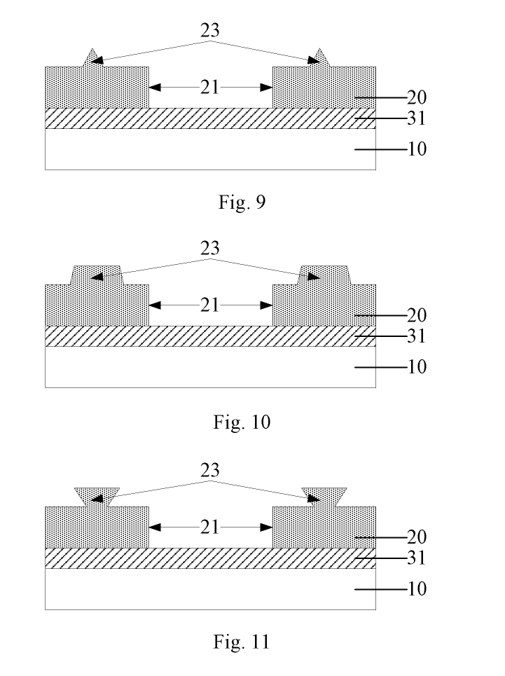

Or, the above-mentioned detoured shape, i.e., a cross-sectional shape of the uneven structure such as the protruded structure 23 along a direction perpendicular to an OLED display panel may comprise, but is not limited to, at least one of a rectangle as shown in FIG. 8, a triangle as shown in FIG. 9, a regular trapezoid as shown in FIG. 10 and an inverted trapezoid as shown in FIG. 11. For example, as for a specific structure of the protruded structure 23, a pixel definition layer PDL of a specific shape may be realized by a photolithographic process, and the process is simple, and is easy to implement. Considering that each of pixel units in a white-light OLED device emits a white light, and each of a plurality of structural layers in the light-emitting function layer 40 is laid on the pixel definition layer 20, and thus it suffers from a relatively serious problem of transverse leakage of conductivity. Therefore, in an embodiment of the disclosure, further optionally, each of the plurality of structural layers in the light-emitting function layer 40 is provided inside the opening holes 21, on the side of the pixel definition layer 20 far away from the substrate 10 and on the uneven structure (for example, inside a recessed structure 22 and/or on a protruded structure 23).

A light-emitting layer in the light-emitting function layer 40 may be formed by laminating light-emitting material layers which emit a red light, a green light and a blue light in sequence, and lights of various colors are mixed together to be displayed as a white light; or, the light-emitting function layer 40 may also be one layer of material, which is doped with light-emitting materials emitting a red light, a green light and a blue light, so that a problem of cross-talk between adjacent pixels in a white-light OLED display substrate can be reduced significantly.

Further, the opening holes 21 on the pixel definition layer 20 are arranged in an array (namely, pixel units are arranged in an array). In at least one row of the opening holes 21, the (one or more) above-mentioned uneven structure such as the (one or more) above-mentioned recessed structure 22 and/or the (one or more) above-mentioned protruded structure 23 is provided between every two adjacent opening holes 21; and/or, in at least one column of the opening holes 21, the (one or more) above-mentioned uneven structure such as the (one or more) above-mentioned recessed structure 22 and/or the (one or more) above-mentioned protruded structure 23 is provided between every two adjacent opening holes 21.

Here, furthermore optionally, the uneven structure such as the recessed structure 22 and/or the protruded structure 23 as mentioned above is provided at the interval of each row and/or each column of the opening holes 21. Namely, the detoured design on the pixel definition layer 20 is distributed evenly over the whole pixel definition layer 20. Thus, the problem of cross-talk caused by transverse leakage of electricity between pixels along the row direction and/or along the column direction can be reduced.

Both the recessed structure 22 and the protruded structure 23 may be also provided on the side of the pixel definition layer PDL far away from the substrate at the same time. However, in consideration of simplifying the fabrication process, embodiments of the disclosure may optionally provide such a detoured design that only the recessed structure 22 or the protruded structure 23 is provided on the pixel definition layer PDL, so as to increase the surface area of the pixel definition layer PDL.

Furthermore, in view of the fact that when a protruded structure 23 is provided on the pixel definition layer PDL, the difficulty of packaging and/or bonding the OLED display substrate will be increased due to unevenness of its surface. Therefore, according to an embodiment of the disclosure, further optionally, the pixel definition layer PDL allows its surface area to be increased by providing the recessed structure 22.

The disclosure will give an exemplary embodiment below for describing a structure of the aforesaid OLED display substrate in detail.

Referring to those as shown in FIG. 1 and FIG. 4 to FIG. 7, there is provided an OLED display substrate, comprising:

A substrate 10 which is partitioned into a plurality of light-emitting regions; the substrate 10 comprises a base substrate and a transistor array layer, wherein the base substrate may be a rigid base such as glass or the like, or a flexible base such as Polyimide (PI) or the like.

A first electrode 31 disposed on the substrate 10 and corresponding to each of the light-emitting regions, the material of the first electrode 31 may be a Transparent Conductive Oxide (TCO), or a nontransparent material such as ITO/Ag/ITO, AlNd or the like.

A pixel definition layer 20 disposed on the substrate 10, there is provided, on the pixel definition layer 20, each of opening holes 21 corresponding to each of the light-emitting regions; on a side of the pixel definition layer 20 far away from the substrate 10, there is also provided a recessed structure 22; and the above-mentioned opening holes 21 expose at least a partial region of the first electrode 31. The pixel definition layer 20 may be of an organic or an inorganic insulating material.

A light-emitting function layer 40 provided above the first electrode 31, the light-emitting function layer 40 may comprise a plurality of structural layers disposed in a laminated manner, such as a hole injection layer, a hole transportation layer, a light-emitting layer, an electron transportation layer, an electron injection layer and so on; wherein at least one of the plurality of structural layers in the light-emitting function layer 40 is provided inside the opening holes 21, on the side of the pixel definition layer 20 far away from the substrate and on the uneven structure (for example, inside the recessed structure 22 and/or on the protruded structure 23), namely, it is laid on the whole layer of the pixel definition layer 20.

A second electrode 32 provided on the light-emitting function layer 40, the material of the second electrode 32 may be a nontransparent metal (e.g., Al, Mg, Ag), or a transparent material such as thin Mg, Ag, TCO or the like.

For example, in order that lights excited from the light-emitting function layer 40 can be transmitted out, at least one of the first electrode 31 and the second electrode 32 is of a transparent material.

The above-mentioned exemplary embodiment has been described with the recessed structure 22 as an example, and it is also applicable to the case of the protruded structure 23. Details thereof will not be repeated any more in embodiments of the disclosure.

Further, according to an embodiment of the disclosure, there is further provided a method of manufacturing an OLED display substrate, comprising:

Step S01, a substrate 10 is provided, the substrate 10 is partitioned into a plurality of light-emitting regions; and a thin film of an insulating material is formed on the substrate 10;

Step S02, a patterning process treatment is conducted on the thin film of the insulating material to form a pixel definition layer 20; wherein each of opening holes 21 corresponding to each of the light-emitting regions is formed on the pixel definition layer 20, and an uneven structure such as a recessed structure 22 and/or a protruded structure 23 is also formed on a side of the pixel definition layer 20 far away from the substrate 10.

Here, the patterning process is, for example, a process that applies one mask, exposes photoresist, develops, etches film layers and removes the photoresist. For example, the mask may be a common mask, or a half-tone mask, or a gray-tone mask, and it can be adjusted flexibly according to the specific patterning process. When the pixel definition layer 20 is formed by a photoresist material, it is possible to form the desired, specific detoured design by exposure and development.

Further, before the step S02, the manufacturing method further comprises: a first electrode 31 corresponding to each of the light-emitting regions is formed on the substrate 10, and at least a partial region of the first electrode 31 is exposed by the opening holes 21 to be formed on a pixel definition layer 20.

After the step S02, the manufacturing method further comprises:

Step S03, a light-emitting function layer 40 is formed, the light-emitting function layer 40 comprises a plurality of structural layers disposed in a laminated manner, such a hole injection layer, a hole transportation layer, a light-emitting layer, an electron transportation layer, an electron injection layer and so on; wherein at least one of the plurality of structural layers in the light-emitting function layer 40 is provided inside the opening holes 21, on the side of the pixel definition layer 20 far away from the substrate and on the uneven structure (for example, inside the recessed structure 22 and/or on the protruded structure 23).

Further, according to an embodiment of the disclosure, there is further provided a display panel, comprising the above-mentioned OLED display substrate and a bonded substrate with respect to the OLED display substrate.

For example, the above-mentioned bonded substrate may be a package cover plate after packaging the OLED display substrate, a touch cover plate to which a touch electrode layer is attached, a color film substrate or the like. Regarding details, the prior art can be followed, and embodiments of the disclosure will have no limitations on this.

Further, according to an embodiment of the disclosure, there is further provided a display apparatus, comprising the above-mentioned display panel. The display apparatus may be, for example, a product or a component having any display function, such as an OLED display, an OLED television, a digital photo frame, a cell phone, a tablet computer, a navigator or the like.

The foregoing descriptions are merely the specific embodiments of the disclosure, but the protection scope of the disclosure is not limited thereto. All changes or replacements, as would be obvious to any of those skilled in the technical field within the technical scope disclosed by the disclosure, shall be embraced within the protection scope of the disclosure. Thus, the protection scope of the disclosure shall be defined by the protection scope of the claims.

What is claimed is:

1. An OLED display substrate, comprising:
a substrate which is partitioned into a plurality of light-emitting regions; and
a pixel definition layer disposed on the substrate, on which each of opening holes corresponding to each of the light-emitting regions is provided,
wherein an uneven structure is also provided on a side of the pixel definition layer far away from the substrate.

2. The OLED display substrate according to claim 1, wherein the uneven structure comprises a recessed structure.

3. The OLED display substrate according to claim 1, wherein the uneven structure comprises a protruded structure.

4. The OLED display substrate according to claim 1, wherein the OLED display substrate further comprises:
a first electrode disposed on the substrate and corresponding to each of the light-emitting regions, the opening holes exposing at least a partial region of the first electrode;
a light-emitting function layer comprising a plurality of structural layers disposed in a laminated manner; wherein at least one of the plurality of structural layers is provided inside the opening holes, on the side of the pixel definition layer far away from the substrate and on the uneven structure.

5. The OLED display substrate according to claim 4, wherein each of the plurality of structural layers in the light-emitting function layer is provided inside the opening holes, on the side of the pixel definition layer far away from the substrate and on the uneven structure.

6. The OLED display substrate according to claim 5, wherein the light-emitting function layer is used to emit a white light.

7. The OLED display substrate according to claim 1, wherein the opening holes are arranged in an array;
in at least one row of the opening holes, the uneven structure is provided between every two adjacent opening holes.

8. The OLED display substrate according to claim 1, wherein the opening holes are arranged in an array;
in at least one column of the opening holes, the uneven structure is provided between every two adjacent opening holes.

9. The OLED display substrate according to claim 1, wherein
a cross-sectional shape of the uneven structure along a direction perpendicular to the OLED display substrate comprises at least one of a rectangle, a triangle, a regular trapezoid or an inverted trapezoid.

10. The OLED display substrate according to claim 4, wherein the OLED display substrate further comprises a second electrode disposed on the light-emitting function layer.

11. The OLED display substrate according to claim 1, wherein the substrate comprises a base substrate and a transistor array layer disposed on the base substrate.

12. A manufacturing method of an OLED display substrate, the manufacturing method comprises:
providing a substrate which is partitioned into a plurality light-emitting regions; forming a thin film of insulating material on the substrate;
conducting a patterning process treatment on the thin film of insulating material to form a pixel definition layer;
wherein each of opening holes corresponding to each of the light-emitting regions is formed on the pixel definition layer, and an uneven structure is also formed on a side of the pixel definition layer far away from the substrate.

13. The manufacturing method according to claim 12, wherein the uneven structure comprises a recessed structure.

14. The manufacturing method according to claim 12, wherein the uneven structure comprises a protruded structure.

15. The manufacturing method according to claim 12, wherein before the step of conducting the patterning process treatment on the thin film of insulating material to form the pixel definition layer, the manufacturing method further comprises:
forming, on the substrate, a first electrode corresponding to each of the light-emitting regions; the opening holes to be formed exposing at least a partial region of the first electrode;
after the step of conducting the patterning process treatment on the thin film of insulating material to form the pixel definition layer, the manufacturing method further comprises:
forming a light-emitting function layer which comprises a plurality of structural layers disposed in a laminated manner; wherein at least one of the plurality of structural layers is provided inside the opening holes, on a side of the pixel definition layer far away from the substrate and on the uneven structure.

16. A display panel, comprising the OLED display substrate according to claim 1 and a bonded substrate with respect to the OLED display substrate.

17. The display panel according to claim 16, wherein the bonded substrate is a package cover plate, or a touch cover plate to which a touch electrode layer is attached, or a color film substrate.

18. A display apparatus, comprising the display panel according to claim 16.
